(19) United States
(12) Patent Application Publication
(10) Pub. No.: US 2010/0058145 A1
(43) Pub. Date: Mar. 4, 2010

(54) STORAGE DEVICE AND METHOD OF CONTROLLING STORAGE DEVICE

(75) Inventor: Osamu Yoshida, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/512,737

(22) Filed: Jul. 30, 2009

(30) Foreign Application Priority Data
Sep. 1, 2008 (JP) 2008-223515

(51) Int. Cl. G11C 29/52; G06F 11/10

(52) U.S. Cl. 714/764; 714/E11.034

(57) ABSTRACT

A control method is for controlling a storage device that writes data in a storage medium including a plurality of groups each having a plurality of sectors and a redundancy sector in which error correction information is stored to perform error correction on data stored in the sectors per each of the groups. The control method includes: rewriting data stored in the sectors included in one of the groups; and writing invalidation data indicating that the error correction information is invalid in the redundancy sector if the error correction information stored in the redundancy sector of the one of the groups has not been rewritten.

### CROSS-REFERENCE TO RELATED APPLICATION

This application is based upon and claims the benefit of priority of the prior Japanese Patent Application No. 2008-223515, filed on Sep. 1, 2008, the entire contents of which are incorporated herein by reference.

### FIELD

The embodiment discussed herein is directed to a storage device including a redundancy sector for performing error correction on data and a method of controlling the storage device.

### BACKGROUND

A storage device that stores therein large volumes of data are used for various applications. This type of storage device typically includes a magnetic disk device, an optical disk device, and a dynamic random access memory (DRAM).

The storage device performs writing and reading of data in response to a command received from an upper-level device such as a central processing unit (CPU). Upon an operation of writing data in the storage device, an error correct code (ECC) is added to each sector having a predetermined data length and then stored in the storage device. Upon a data reading operation, the storage device can perform error correction per sector by using the ECC. A sector in which data received from the upper-level device is written is referred to as a data sector.

If the length of an error that occurs in a data sector is longer than the length of the ECC, the storage device is not allowed to perform the error correction on the data sector by using the ECC. A redundancy sector having the same data length as that of the data sector is used to perform the error correction on the data sector. The redundancy sector stores therein error correction information to correct an error in the data sector. The error correction information is used for correction of an error that occurs in any of a plurality of data sectors constituting one group. The redundancy sector stores therein, as the error correction information, a result of a logical operation performed on data stored in all of the data sectors included in the group at each bit position.

If data has been written in a part of the data sectors included in the group, it is necessary to recalculate the error correction information stored in the redundancy sector corresponding to the group based on all of the data sectors included in the group after the writing operation. However, the recalculation of the error correction information may not be immediately performed due to priority of processing. The error correction information that has not been recalculated is invalid error correction information by which the error in the data sector is not allowed to be properly corrected. To prevent an error correction operation from being performed with the invalid error correction information, Japanese Laid-open Patent Publication No. 2008-77458 and Japanese Laid-open Patent Publication No. 2008-77783 disclose technologies of arranging a table in which data indicating validity or invalidity of a redundancy sector corresponding to each group is stored. It is possible to prevent an improper error correction operation by referring to the table upon the error correction.

The table is stored in a storage medium arranged in a storage device. An error correcting unit that performs the error correction operation may not read the table due to damage of data in the storage medium, or the like. If the error correcting unit may not read the table, the error correcting unit is not allowed to determine validity of the redundancy sector. Therefore, there is a possibility that the error correcting unit performs an improper error correction operation on a data sector.

### SUMMARY

According to an aspect of the invention, a control method is for controlling a storage device that writes data in a storage medium including a plurality of groups each having a plurality of sectors and a redundancy sector in which error correction information is stored to perform error correction on data stored in the sectors per each of the groups. The control method includes: rewriting data stored in the sectors included in one of the groups; and writing invalidation data indicating that the error correction information is invalid in the redundancy sector if the error correction information stored in the redundancy sector of the one of the groups has not been rewritten.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram for illustrating an example of a configuration of a hard disk drive;

FIG. 2 is a block diagram for illustrating an example of a configuration of a redundancy calculating unit;

FIG. 3 is a diagram of bit array of data sectors and a redundancy sector;

FIG. 4 depicts a table of sector array at a user area of a disk medium;

FIG. 5 is a flowchart of an operation performed for determining validity of the redundancy sector;

FIG. 6 is a flowchart of an operation for writing invalidation data in the redundancy sector; and

FIG. 7 is a flowchart of an operation of writing the invalidation data in the redundancy sector.

### DESCRIPTION OF EMBODIMENT

An embodiment of the present invention will be explained below. The embodiment described below can be implemented by processing of a program executed by a processor. Although a hard disk drive is employed as a storage device in the embodiment, the present invention is not limited to the embodiment.

### [Hard Disk Drive]

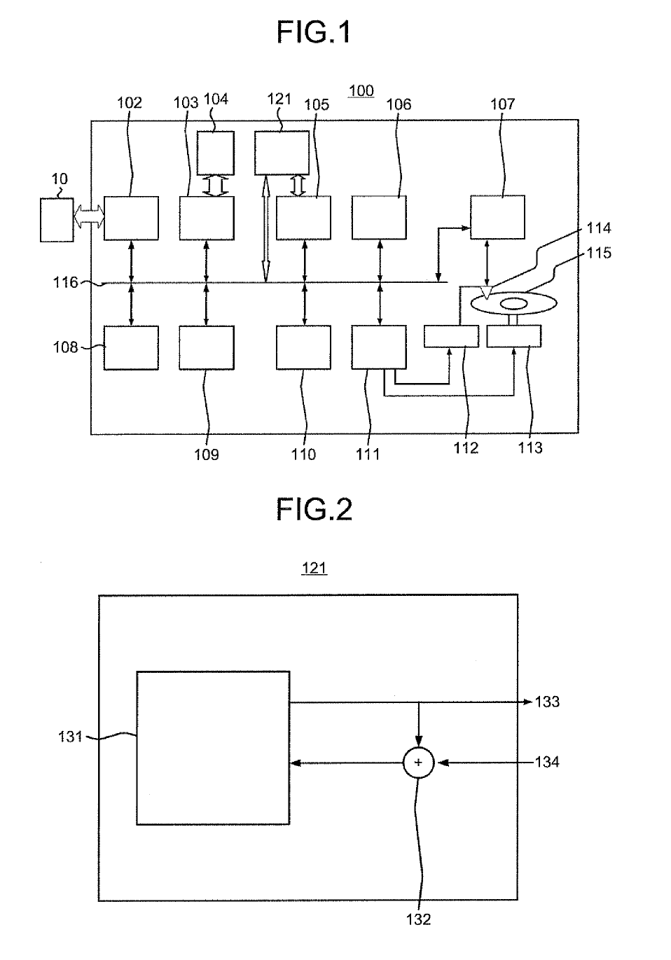

FIG. 1 is a block diagram for illustrating an example of a configuration of a hard disk drive 100 according to the embodiment. The hard disk drive 100 includes a host interface (I/F) control unit 102, a data-buffer control unit 103, a data buffer 104, a format control unit 105, a read channel (RDC) 106, a head integrated circuit (IC) 107, a control unit 108, a memory 109, a nonvolatile memory 110, a disk medium 115, a voice coil motor (VCM) 112, a spindle motor (SPM) 113, a servo control unit 111, a head 114, a common bus 116, and a redundancy calculating unit 121.

The host I/F control unit 102 controls data transaction between an upper-level device 10 such as a personal computer (PC) and the hard disk drive 100. The data-buffer control unit 103 controls writing and reading of data to and from the data buffer 104. A read command transmitted from the upper-level device 10 and data read from the disk medium 115 are temporarily stored in the data buffer 104.

The format control unit 105 adds an error correct code (ECC) to data written from the upper-level device 10. Furthermore, the format control unit 105 performs an error correction operation on data read from the disk medium 115 by using the ECC added to the data upon a writing operation.

The RDC 106 performs code modulation on data to be written in the disk medium 115 and then outputs the data to the head IC 107. Furthermore, the RDC 106 extracts data from signals output from the head IC 107 and then performs code demodulation on the data. The head IC 107 amplifies a signal input from the head 114 and then outputs the signal to the RDC 106. Moreover, the head IC 107 amplifies a signal input from the RDC 106 and then outputs the signal to the head 114.

The control unit 108 controls an operation of the hard disk drive 100 in an integrated manner. The control unit 108 is implemented by, for example, a micro processing unit (MPU). The memory 109 temporarily stores therein control data or a control program to be used by the control unit 108. The nonvolatile memory 110 stores therein a program to be executed by the control unit 108, or the like.

The disk medium 115 is a type of storage medium in which data written from the upper-level device 10 is stored. The VCM 112 generates a drive power to move the head 114 to a predetermined position. The SPM 113 rotates the disk medium 115. The servo control unit 111 controls operations of the VCM 112 and the SPM 113. The common bus 116 is commonly connected to the host I/F control unit 102, the data-buffer control unit 103, the data buffer 104, the format control unit 105, the RDC 106, the head IC 107, the control unit 108, the memory 109, the nonvolatile memory 110, and the servo control unit 111. The redundancy calculating unit 121 generates redundancy sector data based on data written from the upper-level device 10. A detailed operation of the redundancy calculating unit 121 will be explained later.

Data is read from the disk medium 115 in response to a read command received from the upper-level device 10. The read data is converted into electric signals by the head 114, amplified by the head IC 107, and then output to the RDC 106. The RDC 106 performs the code demodulation on the input data and then output the data to the format control unit 105. The format control unit 105 performs ECC calculation on the input data.

If an error does not occur in data as a result of the ECC calculation, the data-buffer control unit 103 writes the data in the data buffer 104. When a certain amount of the data is written in the data buffer 104, the data-buffer control unit 103 reads the data from the data buffer 104. The read data is transmitted to the upper-level device 10 by the host I/F control unit 102.

Data is transmitted from the upper-level device 10 to the host I/F control unit 102 in response to a write command received from the upper-level device 10. The host I/F control unit 102 sends the data to the data-buffer control unit 103. The data-buffer control unit 103 writes the received data in the data buffer 104. The data written in the data buffer 104 is read from the data buffer 104 by the data-buffer control unit 103 at an appropriate timing to be written in the disk medium 115. The read data is output to the format control unit 105. The format control unit 105 generates the ECC from the data, adds the ECC to the data, and then sends the data to the RDC 106. The RDC 106 performs the code modulation on the received data and then sends the data to the head IC 107. The head IC 107 amplifies the received data and then writes the data in the disk medium 115.

### [Redundancy Calculating Unit]

FIG. 2 is a block diagram for illustrating an example of the configuration of the redundancy calculating unit 121 according to the embodiment. The redundancy calculating unit 121 generates error correction information by using data stored in a plurality of data sectors included in each group. The redundancy calculating unit 121 includes an operation result memory 131 and an exclusive OR (XOR) calculating unit 132. The operation result memory 131 has a capacity corresponding to a size of a sector and stores therein operation result data 133 corresponding to one sector.

The XOR calculating unit 132 performs an XOR operation on input data 134 corresponding to one sector received from an external device and the operation result data 133 corresponding to one sector stored in the operation result memory 131 at each bit position. An operation result is written as new operation result data 133 in the operation result memory 131. Specifically, the redundancy calculating unit 121 performs the XOR operation on a logical value of the N-th bit of the input data 134 and a logical value of the N-th bit of the operation result data 133 and writes an operation result thereof as data on the N-th bit of the new operation result data 133 in the operation result memory 131. The control unit 108 reads the operation result data 133 stored in the operation result memory 131 via the common bus 116 and writes the read operation result data 133 as the error correction information in a redundancy sector of the disk medium 115.

### [Bit Operation]

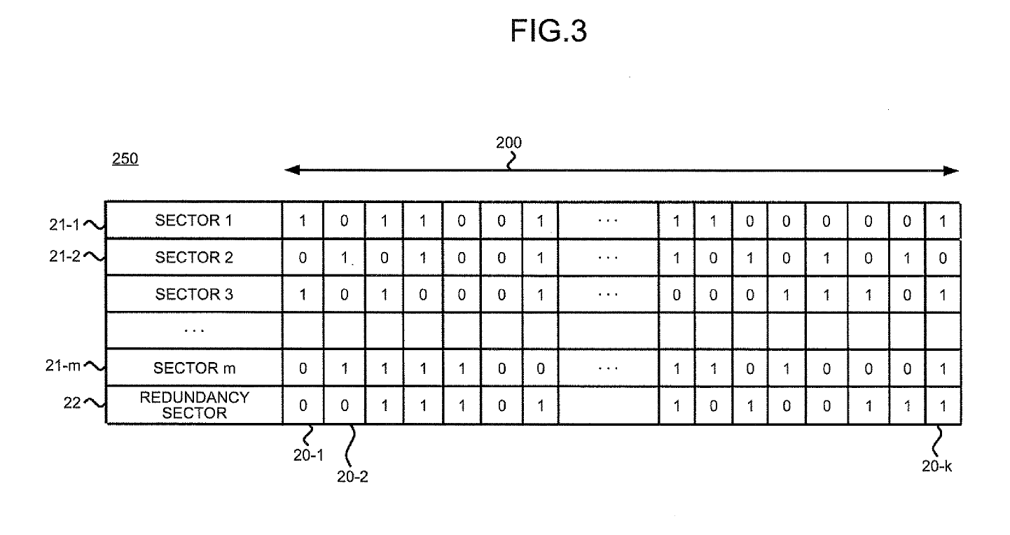

FIG. 3 depicts a bit array table 250 of data sectors and a redundancy sector included in one of a plurality of groups stored in the disk medium 115. The data sector stores therein data written from the upper-level device 10. A bit length 200 indicates a bit length of each of the sectors. The group includes the m number of data sectors. The number m is a natural number larger than 1. A row 21-1 indicates the first row of the bit array table 250. A row 21-m indicates the m-th row of the bit array table 250. Each of the rows 21-1 to 21-m indicates a data sector in which data written from the upper-level device 10 is stored. A row 22 indicates a redundancy sector corresponding to the data sectors.

A column 20-1 indicates the first column of the bit array table 250. The number of bits in each of the sectors is k. The bit number k is a natural number larger than 1. A column 20-k indicates the k-th column of the bit array table 250. Each of the columns 20-1 to 20-k indicates logical values of the sectors at each bit position. The XOR calculating unit 132 performs the XOR operation on the data sectors from the rows 21-1 to 21-m in each of the columns 20-1 to 20-k, and writes an operation result thereof in the row 22 that is the redundancy sector. Thus, a result of the XOR operation performed on all of the data sectors included in the group is written in the row 22.

### [Sector Array]

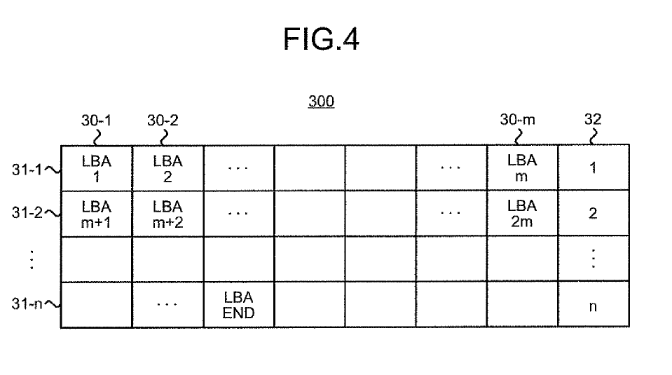

FIG. 4 depicts an array table 300 for illustrating an example of sector array at a user area of the disk medium 115 according to the embodiment. The user area is an area other than a system area assigned for the upper-level device 10 to drive a system.

Each element included in the array table 300 indicates a sector having a certain data length. One group includes the m number of data sectors. The m number of the rows in the bit array table 250 is the same as the m number of columns in the array table 300. A column 30-1 indicates the first column of the array table 300. A column 30-m indicates the m-th column of the array table 300. Each of the columns 30-1 to 30-m indicates a data sector in which data written from the upper-level device 10 is stored. An address for identifying a data sector is assigned to each of the data sectors, and the address is referred to as a logical block address (LBA). A column 32 indicates a redundancy sector in which redundancy sector data is written.

A row 31-1 indicates the first row of the array table 300. A row 31-n indicates the n-th row of the array table 300. The number n is a natural number larger than 1. Each of the rows 31-1 to 31-n indicates each of the groups written in the disk medium 115. Each of the groups includes the m number of data sectors and one redundancy sector. Each redundancy sector data is calculated based on the data sectors included in the group to which the redundancy sector belongs.

The redundancy sector is used in a manner as described below. It is assumed that an error that may not be corrected with an error correction capability by means of the ECC occurs in one of the groups from the rows 31-1 to 31-n. The control unit 108 reads data stored in all of the data sectors except an error sector included in the one of the groups from the rows 31-1 to 31-n and data stored in the redundancy sector corresponding to the group from the disk medium 115. The control unit 108 sends the read data to the redundancy calculating unit 121. The redundancy calculating unit 121 performs the XOR operation on the received data. An operation result is equivalent to data stored in the data sector corresponding to the error sector before the error occurs in the error sector. The control unit 108 writes data as the operation result in the sector where the error occurs. In this manner, by preparing the redundancy sector data, the control unit 108 can restore the sector in which the error may not be corrected by means of the ECC, and correct the error.

If data is rewritten in a part of the data sectors included in the groups from the rows 31-1 to 31-n, data stored in the redundancy sector corresponding to the group including the part of the data sectors is invalid, that is, may not be used for correction of an error that occurs in the group. Therefore, an operation for determining that the redundancy sector is invalid is performed as described below. This makes it possible to surely prevent an improper error correction operation by using the invalid redundancy sector. Furthermore, because it is not necessary to arrange a table in which data indicating validity or invalidity of the redundancy sector is stored, it is possible to use a storage area more effectively.

### [Determination on Validity of Redundancy Sector]

Upon an operation of writing data in the disk medium 115, the redundancy calculating unit 121 performs the XOR operation on each of the data sectors, thereby generating error correction information to be stored in the redundancy sector at the same time the redundancy calculating unit 121 writes the data in the disk medium 115. If data is rewritten in all data sectors included in a group, the error correction information stored in the redundancy sector corresponding to the group is simultaneously recalculated. The recalculated error correction information stored in the redundancy sector is valid, that is, can make it possible to properly perform the error correction on the data sectors.

On the other hand, if data is rewritten in a part of the data sectors included in the group, the redundancy calculating unit 121 performs the XOR operation on only the part of the data sectors. The error correction information corresponding to a group is obtained by performing the XOR operation on all data sectors belonging to the group. Therefore, the error correction information obtained by performing the XOR operation on only a part of the data sectors included in the group is invalid by which the error correction may not be properly performed.

To make valid the invalid error correction information, it is necessary for the redundancy calculating unit 121 to perform the calculation operation again by using all of the data sectors included in the group after the data is rewritten. For the calculation operation, the control unit 108 reads all of the data sectors included in the group from the disk medium 115. The control unit 108 causes the redundancy calculating unit 121 to generate the error correction information by using all of the read data sectors. The control unit 108 writes the generated error correction information in the redundancy sector corresponding to the group. Because such a calculation operation have heavy load on the control unit 108, a data writing operation is interrupted. Therefore, sometimes the recalculation of the error correction information is not performed immediately after data is rewritten in a part of the data sectors included in the group.

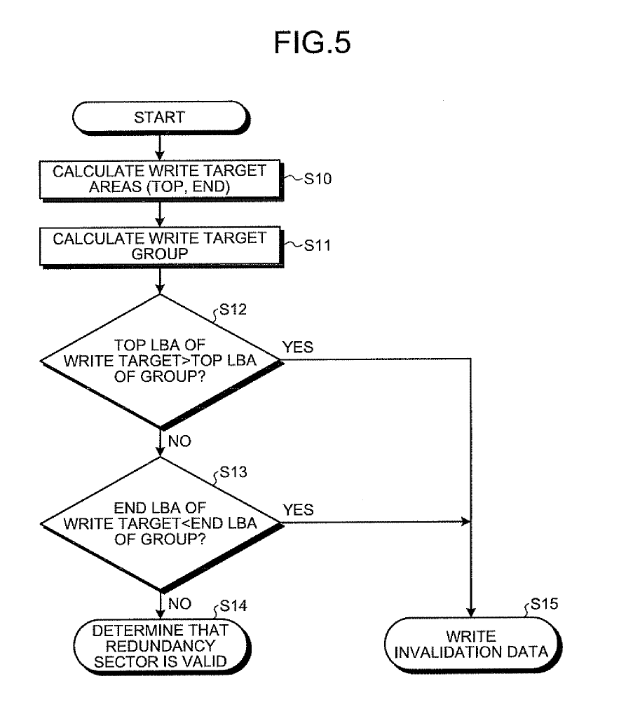

FIG. 5 is a flowchart of an operation performed for determining whether data is written in the whole group or a part of the group in the disk medium 115. The control unit 108 determines validity of the redundancy sector by the operation depicted in FIG. 5. A write command received from the upper-level device 10 is stored in the memory 109. The write command includes information about the LBA of a write target and the number of sectors in which data is to be written. The control unit 108 calculates the top LBA and the end LBA of the write target from the write command (Step S10).

The control unit 108 calculates a write target group from the array table 300 depicted in FIG. 4 based on the leading LBA. The control unit 108 then calculates the top LBA and the end LBA of the group (Step S11). If the top LBA of the write target is larger than the top LBA of the group (Yes at Step S12), the control unit 108 performs an operation of writing invalidation data in the redundancy sector (Step S15). If the top LBA of the write target is smaller than the top LBA of the group (No at Step S12), the control unit 108 compares the end LBA of the write target with the end LBA of the group. If the end LBA of the write target is smaller than the end LBA of the group (Yes at Step S13), the control unit 108 determines that data is rewritten in a part of the group and the error correction information stored in the redundancy sector is invalid. If the control unit 108 determines that the error correction information stored in the redundancy sector is invalid, the control unit 108 performs the operation of writing the invalidation data as described later (Step S15).

Upon the operation of writing the validation data in the redundancy sector, the control unit 108 may calculate a distance from a current position of a head to a sector corresponding to the write command received from the upper-level device 10 and a distance from the current position of the head to the redundancy sector. As a result of the calculation, the control unit 108 rewrites data or writes invalidation data in the redundancy sector located nearby the current position of the head. Thus, the control unit 108 can reduce a wasteful head travel distance upon the data writing operation and perform the data writing operation at a higher speed.

If the end LBA of the write target is larger than the end LBA of the group (No at Step S13), the control unit 108 determines that data is rewritten in the whole group and the error correction information stored in the redundancy sector is valid (Step S14). As described above, the control unit 108 can determine whether the error correction information is valid or invalid at the stage when the data is written. In the embodiment, because the error correction information is generated at the same time the data is written, the error correction information is invalid only if data is rewritten in a part of the group.

If the error correction information is generated again after the data writing operation is performed, invalidity of the error correction information can be determined based on whether data is rewritten in a part or all of the data sectors included in the group. Thus, it is possible to simplify and speed up an operation of determining validity of the error correction information.

### [Writing of Invalidation Data]

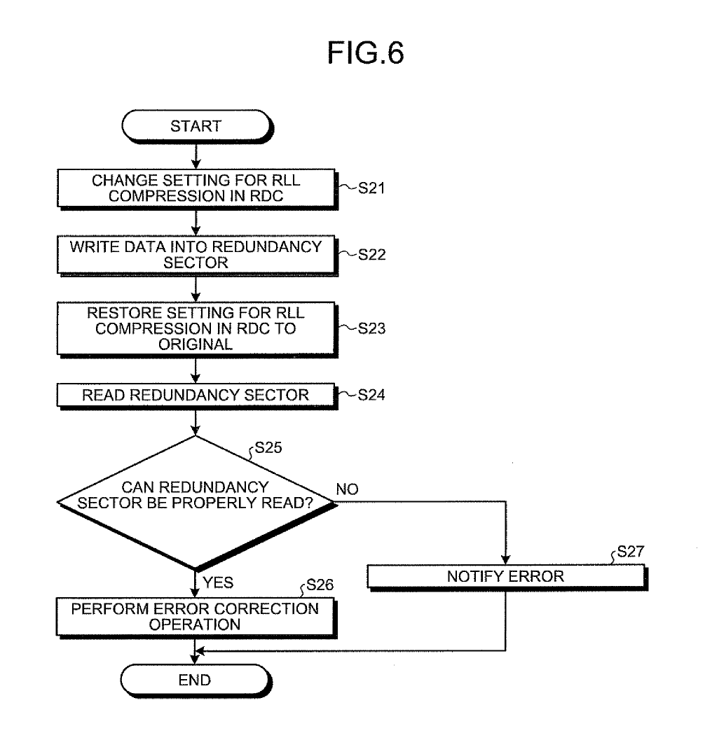

FIG. 6 is a flowchart of an operation for writing the invalidation data in a redundancy sector corresponding to a group if it is determined that the error correction information stored in the redundancy sector is invalid.

If it is determined that data is rewritten in a part of the group by the operation depicted in FIG. 5, the control unit 108 changes a compression rate of the Run Length Limited (RLL) coding in the RDC 106 (Step S21). The RLL coding is a recording method used for recording data in a high density. Different compression rates of the RLL coding are employed upon the writing operation and the reading operation, so that a read error can occur in the RDC 106.

The control unit 108 writes data into a redundancy sector corresponding to a group in which it is determined that data is rewritten in a part of the group with the changed compression rate (Step S22). After the data is written, the control unit 108 restores the changed compression rate in the RDC 106 to the original compression rate (Step S23). If an error is detected in a data sector upon the data reading operation, the format control unit 105 performs the error correction operation by using the ECC. If the error in the data sector may not be corrected by using the ECC, the control unit 108 performs the operation of reading the redundancy sector corresponding to the data sector to perform the error correction operation on the data sector (Step S24).

As described above, if the data written in the redundancy sector by the RDC 106 with the changed compression rate is to be read by the RDC 106 with the original compression rate, a read error occurs. The read error means that the same data as that written upon the writing operation is not allowed to be read. The control unit 108 can determine that the data stored in the redundancy sector is invalidation data due to the occurrence of the read error. If data can be properly read from the redundancy sector (Yes at Step S25), the control unit 108 performs the error correction operation on the data sector (Step S26). On the other hand, if the data is not allowed to be properly read from the redundancy sector (No at Step S25), the control unit 108 may not perform the error correction operation on the data sector because the data stored in the redundancy data is invalidation data. Therefore, the control unit 108 performs an operation of notifying the upper-level device 10 of an error and terminates the error correction operation (Step S27). Because it is determined that the data stored in the redundancy sector is invalidation data by means of the read error, the control unit 108 does not need to evaluate the read data; therefore, it is possible to speed up the operation of determining the invalidation data.

Alternatively, the control unit 108 may stop an ECC operation of the format control unit 105 (Step S21). The control unit 108 writes data in the redundancy sector while the ECC operation is stopped (Step S22). Thus, the data without the ECC is written in the redundancy sector. After the data is written in the redundancy sector, the control unit 108 resumes the ECC operation of the format control unit 105 (Step S23). If the format control unit 105 reads the redundancy sector after the ECC operation is resumed, a read error occurs because of the absence of the ECC. It can be determined that the data stored in the redundancy sector is invalidation data because of the occurrence of the read error.

### [Writing of Specific Pattern]

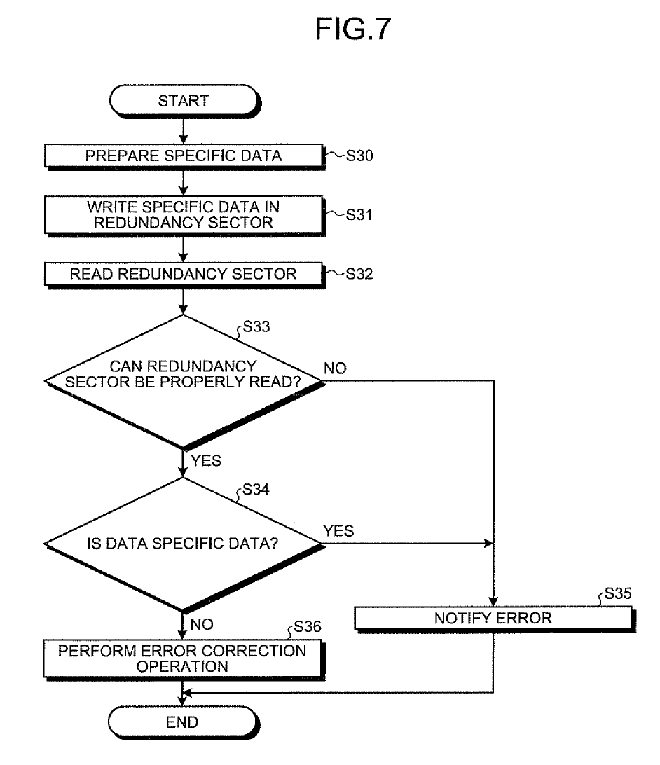

FIG. 7 is a flowchart of an operation of writing invalidation data having a specific pattern in a redundancy sector corresponding to a group if it is determined that the redundancy sector is invalid.

The invalidation data having the specific pattern is stored in the data buffer 104 when the hard disk drive 100 is started up (Step S30). The specific pattern is used to determine that data stored in the redundancy sector is invalid. If it is determined that data is rewritten in a part of the group by the operation depicted in FIG. 5, the control unit 108 writes the specific pattern in the redundancy sector (Step S31).

If an error is detected in a data sector upon the data reading operation, the format control unit 105 performs the error correction operation by using the ECC. If the error in the data sector may not be corrected by using the ECC, the control unit 108 performs the operation of reading the redundancy sector corresponding to the data sector to perform the error correction on the data sector (Step S32).

The control unit 108 instructs the RDC 106 to read the redundancy sector. The RDC 106 performs the operation of reading the redundancy sector. If the operation of reading the redundancy sector fails (No at Step S33), the RDC 106 notifies the control unit 108 of an error. Because the control unit 108 is not allowed to perform the error correction operation by using the redundancy sector, the control unit 108 transmits an error notification signal to the upper-level device 10 (Step S35). On the other hand, if the operation of reading the redundancy sector succeeds (Yes at Step S33), the RDC 106 sends data read from the redundancy sector to the memory 109.

The control unit 108 compares the redundancy sector data temporarily stored in the memory 109 with the specific pattern stored in the data buffer 104. If the data corresponds to the specific pattern as a result of the comparison (Yes at Step S34), the control unit 108 transmits the error notification signal to the upper-level device 10. On the other hand, if the data temporarily stored in the memory 109 does not correspond to the specific pattern as a result of the comparison (No at Step S34), the control unit 108 performs the error correction operation by using the redundancy sector data temporarily stored in the memory 109 (Step S36).

The specific pattern may be stored on the system area of the disk medium 115. Thus, a user can rewrite the specific pattern after the hard disk drive 100 is shipped. The control unit 108 may also generate random numbers having the data length of a sector and store the random numbers on the system area as specific data. Furthermore, data having the same logical value, for example, 0 or 1, at each bit position may be defined as the specific pattern. If the data having such a simple bit array is defined as the specific pattern, a bit array of a valid redundancy sector can be determined to be invalid. However, because it is not likely that the logical values at all bit positions of the error correction information are the same, even the valid redundancy sector is processed as the invalid redundancy sector. Thus, it is possible to prevent complexity of the determination operation and a longer processing time.

According to the embodiment, it is possible to surely prevent an error that occurs in the storage device from being corrected with invalid error correction information per sector. Furthermore, because it is not necessary to arrange a table where data indicating validity or invalidity of the error correction information is stored, it is possible to use a storage area more effectively.

The above operation can be performed in such a manner that the control unit 108 executes a program stored in the memory 109, or the like. The program can be stored in a computer-readable recording medium. The computer-readable recording medium includes a magnetic storage device, an optical disk, or a semiconductor memory.

Although the magnetic disk device including the storage medium fixedly mounted on the inside of the magnetic disk device is explained in the embodiment, it is possible to configure a control unit and a control method in a similar manner in a storage device that can include a storage medium including a plurality of groups each having a plurality of sectors and a redundancy sector in which error correction information is stored to perform error correction on data stored in the sectors per group. Such a storage device includes a redundancy calculating unit that, when the storage medium is mounted on the storage device, generates the error correction information by using data stored in the sectors included in each of the groups and a control unit that, when the storage medium is mounted on the storage device, rewrites the data stored in a sector, and if the error correction information stored in a redundancy sector corresponding to the group to which the sector belongs has not been rewritten, writes invalidation data indicating that the error correction information is invalid in the redundancy sector. The storage device on which the storage medium is detachably mounted includes an optical disk device or a magnet-optical disk device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present inventions has been described in detail, it should be understood that the various changes, substitutions, and alterations could be made hereto without departing from the spirit and scope of the invention.

What is claimed is:

1. A control method of controlling a storage device that writes data in a storage medium including a plurality of groups each having a plurality of sectors and a redundancy sector in which error correction information is stored to perform error correction on data stored in the sectors per each of the groups, the control method comprising:
rewriting data stored in the sectors included in one of the groups; and
writing invalidation data indicating that the error correction information is invalid in the redundancy sector if the error correction information stored in the redundancy sector of the one of the groups has not been rewritten.

2. The control method according to claim 1, further comprising:
writing data of the sectors in the storage medium with a first compression rate;
changing the first compression rate in accordance with a first data conversion pattern;
reading the data from the storage medium with a second compression rate different from the first compression rate; and
writing, if a read error occurs in the reading, the invalidation data compressed by a second data conversion pattern different from the first data conversion pattern in the redundancy sector.

3. The control method according to claim 1, wherein every value of the invalidation data stored in the redundancy sector is same.

4. A storage device that writes data in a storage medium including a plurality of groups each having a plurality of sectors and a redundancy sector in which error correction information is stored to perform error correction on data stored in the sectors per each of the groups, the storage device comprising:
a redundancy calculating unit that generates the error correction information by using the data stored in the sectors; and
a control unit that rewrites data stored in the sectors included in one of the groups and, if the error correction information stored in the redundancy sector of the one of the groups has not been rewritten, writes invalidation data indicating that the error correction information is invalid in the redundancy sector.

5. The storage device according to claim 4, wherein if an error is detected in the sectors included in one of the groups when data is to be read from the sectors, the control unit reads data from the redundancy sector of the one of the groups, and if read data is the validation data, the control unit does not use the error correction information stored in the redundancy sector of the one of the groups.
